(19) United States
(12) Patent Application Publication
(10) Pub. No.: US 2018/0275079 A1
(43) Pub. Date: Sep. 27, 2018

(54) Radiation Analyzing Apparatus

(71) Applicant: Hitachi High-Tech Science Corporation, Tokyo (JP)

(72) Inventors: Keiichi Tanaka, Tokyo (JP); Kazuo Chinone, Tokyo (JP)

(73) Assignee: Hitachi High-Tech Science Corporation, Tokyo (JP)

(21) Appl. No.: 15/928,807

(22) Filed: Mar. 22, 2018

(30) Foreign Application Priority Data
Mar. 24, 2017 (JP) 2017-059066

(51) Int. Cl. G01N 23/2252; H01J 37/285; H01J 37/244

(52) U.S. Cl. CPC G01N 23/2252; H01J 37/285; H01J 2237/24507; G01N 2223/079; H01J 2237/063; H01J 37/244

(57) ABSTRACT

The radiation analyzing apparatus irradiates an object including a plurality of elements with a first radiation, detects a plurality of rays of a second radiation emitted from the object irradiated with the first radiation, derives an energy spectrum based on a signal of each of the plurality of rays of the second radiation, detects detection energy, which is energy absorbed in a reference element that is an element used as a reference or is energy emitted from the reference element, based on the energy spectrum, and corrects the energy spectrum based on reference energy information, which is previously stored in a storage unit and indicates reference energy that is energy absorbed in the reference element or is energy emitted from the reference element, and the detection energy.

### CROSS-REFERENCE TO RELATED APPLICATION

This application claims priority from Japanese Patent Application No. 2017-059066, filed on Mar. 24, 2017, the entire subject matters of which is incorporated herein by reference.

### BACKGROUND

### 1. Field of the Invention

The present invention relates to a radiation analyzing apparatus.

### 2. Background Art

The study and development of a technique for irradiating an object with radiation and analyzing the properties and structure of the object have been conducted.

In this regard, an X-ray analyzing apparatus having a superconductive Transition Edge Sensor (TES) and a superconducting quantum interference device type amplifier that reads out a change in current of the superconductive transition edge sensor is known.

In this X-ray analyzing apparatus, when certain radiation is incident upon the superconductive transition edge sensor, an electric signal output from the superconductive transition edge sensor is amplified by the superconducting quantum interference device type amplifier, and then is output to another device. When a current having a predetermined current value flows to the superconducting quantum interference device type amplifier, and the radiation is incident upon the superconductive transition edge sensor, the superconductive transition edge sensor outputs the current having the current value as a baseline (an electric signal in this case). Here, when certain radiation is incident upon the superconductive transition edge sensor, a peak value of the electric signal output from the superconductive transition edge sensor is made to correspond to energy corresponding to the peak value. When the aforementioned baseline varies, that is, when the current value of the current flowing to the superconducting quantum interference device type amplifier varies, the peak value varies depending on the variation of the current value. As a result, actual energy of the radiation may not be matched with energy of the radiation derived based on the peak value. That is, this means that detection sensitivity of the superconductive transition edge sensor varies depending on a variation of the baseline. When the detection sensitivity varies, an energy resolution of the superconductive transition edge sensor is reduced. Due to such circumstances, in the X-ray analyzing apparatus, to improve the energy resolution of the superconductive transition edge sensor (i.e., to uniformly maintain the detection sensitivity of the superconductive transition edge sensor), unit for correcting a peak value when the current flowing to the superconducting quantum interference device type amplifier (i.e., the current flowing to the superconductive transition edge sensor) is changed to a peak value before the change is required.

In JP-A-2009-271016, as an apparatus making a current of a baseline constant, an X-ray analyzing apparatus is disclosed in which, when a current value of a current flowing to a superconductive transition edge sensor deviates from a predetermined current value, the baseline is corrected depending on the deviation from the current value, or a peak value based on the baseline is corrected.

In JP-A-2014-38074, a radiation analyzing apparatus is disclosed in which a peak value based on a baseline is corrected based on output of a heater incorporated in a seat on which a superconductive transition edge sensor is installed or a correlation with the baseline. The radiation analyzing apparatus previously acquires information indicating the output of the heater and the correlation with the baseline, and corrects the peak value of a signal output by the superconductive transition edge sensor using the baseline corresponding to the output of the heater when the signal is acquired from the superconductive transition edge sensor.

In JP-A-2016-133411, a technique for reducing a statistical error when a baseline is corrected based on output of a heater incorporated in a seat on which a superconductive transition edge sensor is installed is disclosed.

Even when the baseline is kept constant, the energy of the radiation calculated based on the peak value of the electric signal output from the superconductive transition edge sensor when certain radiation is incident upon the superconductive transition edge sensor may not be matched with the actual energy of the radiation. Non-patent documents 1 and 2 represented below explains that there is a case in which an energy spectrum of radiation emitted from the object is changed due to a state of an object to be analyzed by an X-ray analyzing apparatus. The state means a state in which a plurality of elements of which the object is composed are each chemically bonded.
[Non-Patent Document 1] Hiroyoshi Soejima, “Electron probe microanalysis,” NIKKAN KOGYO SHIMBUN, LTD., 1987, pp. 426-427
[Non-Patent Document 2] Noro Hisato, Sato Kaoru, Tanaka Keiichi, “Advantages of Transition-Edge Sensor Combined with Low Voltage SEM in Surface Analysis,” 2010, Surface Science Vol. 31, No. 11, pp. 610-615 In this way, the X-ray analyzing apparatus as a related art utilizes a sensitivity correcting unit for correcting a peak value 1 mentioned below to a peak value 0 mentioned below, in order to suppress the unconformity between the peak value (as the peak value 1) corresponding to the energy of the radiation calculated based on the peak value of the electric signal output from the superconductive transition edge sensor when certain radiation is incident upon the superconductive transition edge sensor and the peak value (as the peak value 0) corresponding to the actual energy of the radiation. However, it is necessary for utilizing the sensitivity correcting unit to previously obtain a correlation between the aforementioned output of the heater and the correction factor or between the baseline and the correction factor. As a result, it might be difficult for the X-ray analyzing apparatus to reduce a time and an effort required for the analysis of the object.

### SUMMARY

The object of the present invention is to provide a radiation analyzing apparatus that enables to provide a high-precision energy spectrum while reducing a time required for an analysis of an object.

According to an exemplary embodiment of the present disclosure, there is provided a radiation analyzing apparatus having:

an excitation source unit configured to irradiate an object including a plurality of elements with a first radiation;

a radiation detection unit configured to detect a plurality of rays of a second radiation emitted from the object irradiated with the first radiation;

a derivation unit configured to derive an energy spectrum based on a signal of each of the plurality of rays of the second radiation detected by the radiation detection unit;

a detection unit configured to detect detection energy, which is energy absorbed in a reference element that is an element used as a reference or is energy emitted from the reference element, based on the energy spectrum derived by the derivation unit, and

a correction unit configured to correct the energy spectrum derived by the derivation unit based on reference energy information, which is previously stored in a storage unit and indicates reference energy that is energy absorbed in the reference element or is energy emitted from the reference element, and the detection energy detected by the detection unit.

According to the present invention, there can be provided the radiation analyzing apparatus that enables to provide a high-precision energy spectrum while reducing a time required for an analysis of an object.

### BRIEF DESCRIPTION OF THE DRAWINGS

FIG. 1 is a diagram illustrating an example of a configuration of a radiation analyzing apparatus according to an embodiment.

FIG. 2 is a diagram illustrating an example of a configuration of a radiation detection unit 12 having a superconductive transition edge sensor T1.

FIG. 3 is a diagram illustrating an example of functional configurations of a first control device and a second control device.

FIG. 4 is a flow chart illustrating an example of a flow of a process in which the second control device 40 corrects an energy spectrum.

FIG. 5 is a graph illustrating an example of a first energy spectrum derived by a derivation unit 462 in step S150.

### DETAILED DESCRIPTION

### Embodiment

Hereinafter, an embodiment of the present invention will be described with reference to the drawings.

### <Configuration of Radiation Analyzing Apparatus>

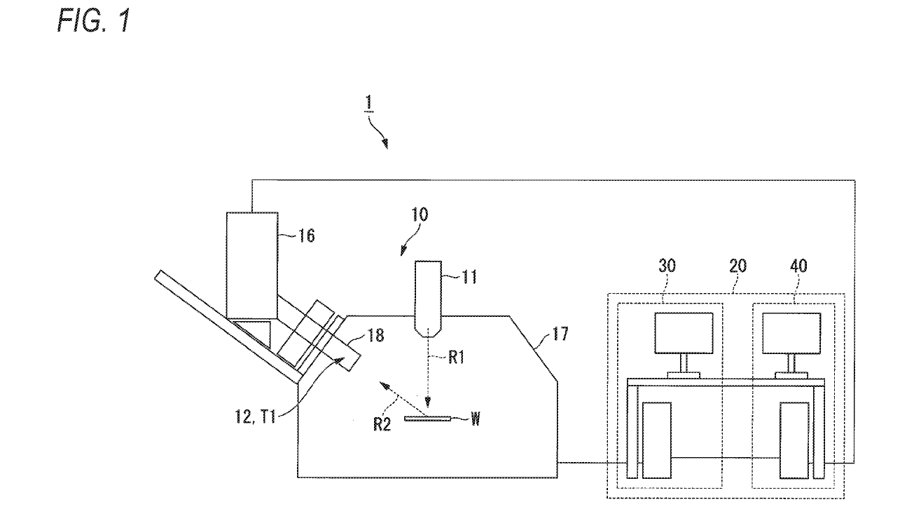

First, a configuration of a radiation analyzing apparatus 1 will be described with reference to FIG. 1.

FIG. 1 is a diagram illustrating an example of a configuration of the radiation analyzing apparatus 1 according to the embodiment.

The radiation analyzing apparatus 1 includes a detection device 10 and a control device 20. The detection device 10 includes an excitation source unit 11, a radiation detection unit 12, a cooling device 16 and a housing 17.

The excitation source unit 11 irradiates an object with first radiation R1. The excitation source unit 11 is, for example, an electron gun. In this case, the first radiation R1 is an electron beam. Instead of the electron gun, the excitation source unit 11 may be a device that emits radiation, which is different from an electron beam such as X-rays, a focused ion beam produced by focusing positive ions, a focused ion beam produced by focusing negative ions, various meson beams, a neutrino beam, or the like. In this case, the first radiation R1 is radiation that the excitation source unit 11 can irradiate. A proton beam used in proton induced X-ray emission (PIXE) is included in the focused ion beam produced by focusing the positive ions instead of the electron gun.

The radiation detection unit 12 detects second radiation R2 that is generated from the object irradiated with the first radiation R1. The radiation detection unit 12 includes, for example, a superconductive transition edge sensor (TES) T1, and detects the second radiation R2 using the superconductive transition edge sensor T1. Hereinafter, a description will be given of an example of a case in which the second radiation R2 is characteristic X-rays such as fluorescent X-rays, which is generated from the object. That is, the radiation analyzing apparatus 1 is a superconductive X-ray analyzing device in this example. Meanwhile, the second radiation R2 may be another radiation such as an electron beam, a meson beam, instead of the X-rays. In this case, the radiation analyzing apparatus 1 is an apparatus that analyzes the object using the other radiation. In addition, the radiation detection unit 12 may be configured to detect the second radiation R2 using another detection element, instead of being configured to detect the second radiation R2 using the superconductive transition edge sensor T1.

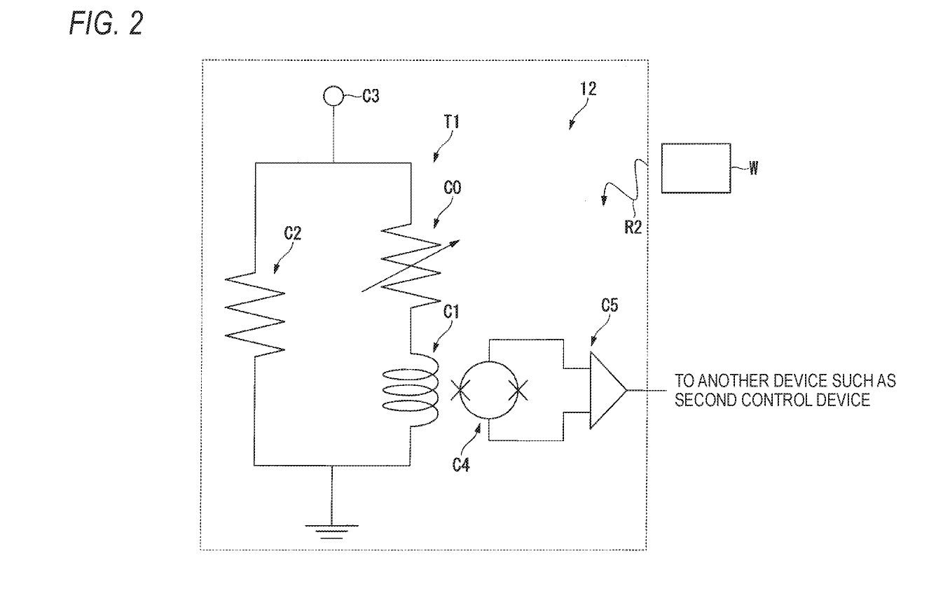

Here, the superconductive transition edge sensor T1 will be described. The superconductive transition edge sensor T1 detects the second radiation R2 using a change in resistance generated when X-rays (i.e., the second radiation R2 in this example) are incident upon a metal thin film C0 in a superconductive state. That is, the metal thin film C0 behaves as a microcalorimeter. FIG. 2 is a view illustrating an example of a configuration of the radiation detection unit 12 having the superconductive transition edge sensor T1. The radiation detection unit 12 includes the superconductive transition edge sensor T1, a bias power supply C3, a superconducting quantum interference device type amplifier C4, and a room temperature amplifier C5. The superconductive transition edge sensor T1 is a ring circuit that includes the metal thin film C0, an input coil C1, and a shunt resistor C2 having a smaller resistance value than the metal thin film C0. In the superconductive transition edge sensor T1, the metal thin film C0 and the input coil C1 are connected, and the metal thin film C0 and the input coil C1 are connected to the shunt resistor C2 in parallel. In the ring circuit, a ground is connected between the input coil C1 and the shunt resistor C2. In the ring circuit, the bias power supply C3 is connected between the metal thin film C0 and the shunt resistor C2. A pseudo constant voltage is applied to the ring circuit by the bias power supply C3.

A current flowing to the metal thin film C0 is detected as a magnetic field signal by the superconducting quantum interference device type amplifier C4 in which a plurality of superconducting quantum interference devices operated at a liquid nitrogen temperature (77K) or lower are connected in series via the input coil C1, then is converted into an electric signal, and is amplified. An output signal from the superconducting quantum interference device type amplifier C4 is sent to the room temperature amplifier C5. The output signal sent to the room temperature amplifier C5 is shaped and amplified, and is output to another device such as the control device 20.

When the X-rays are incident upon the metal thin film C0 in the superconductive state, a temperature of the metal thin film C0 rises, and the state of the metal thin film C0 transitions to a normally conductive state from the superconductive state. At this time, electric resistance of the metal thin film C0 is sharply changed in proportion to energy (that is, the rising temperature of the metal thin film C0) of the X-rays incident upon the metal thin film C0 (for example, a change in resistance is 0.1 □ or the like when a change in temperature is several mK). Here, since the pseudo constant voltage is applied to the superconductive transition edge sensor T1 by the bias power supply C3, the current flowing to the metal thin film C0 is reduced. As a result, a change in current of the superconductive transition edge sensor T1 occurs. The superconducting quantum interference device type amplifier C4 reads out this change in current of the superconductive transition edge sensor T1.

To be more specific, in the radiation detection unit 12, when certain radiation is incident upon the superconductive transition edge sensor T1, an electric signal output from the superconductive transition edge sensor T1 is amplified by the superconducting quantum interference device type amplifier C4, and is then output to another device. When a current of a predetermined current value flows to the superconducting quantum interference device type amplifier C4 and the radiation is not incident upon the superconductive transition edge sensor T1, the superconductive transition edge sensor T1 outputs the current of the current value as a baseline (in this case, an electric signal). When the radiation is incident upon the superconductive transition edge sensor T1, the radiation detection unit 12 outputs an electric signal of a peak value proportional to energy of the radiation to the control device 20 as detection information indicating that the second radiation R2 is detected. Here, when the baseline varies, the peak value of the electric signal is changed depending on the variation of the baseline.

Returning to FIG. 1, the radiation detection unit 12 is disposed inside a thermal shield 18. The thermal shield 18 shields radiant heat from the outside of the thermal shield 18, and suppresses a rise in temperature inside the thermal shield 18. That is, the thermal shield 18 suppresses a rise in the temperature of the radiation detection unit 12 due to the radiant heat. Thus, the superconductive state of the superconductive transition edge sensor T1 included in the radiation detection unit 12 is held until X-rays are incident upon the superconductive transition edge sensor T1.

The cooling device 16 cools the inside of the thermal shield 18. Thus, the cooling device 16 can set a state of the superconductive transition edge sensor T1 included in the radiation detection unit 12 disposed inside the thermal shield 18 to be a superconductive state. The cooling device 16 cools the inside of the thermal shield 18 using a cooling control device (not shown).

The housing 17 is a housing of the detection device 10. In this example, an irradiation port through which the first radiation R1 is emitted from the radiation irradiation unit 11, an object that is irradiated with the first radiation R1 from the radiation irradiation unit 11, and the radiation detection unit 12 disposed inside the thermal shield 18 are disposed inside the housing 17. In the example illustrated in FIG. 1, an object W irradiated with the first radiation R1 is disposed inside the housing 17. Details of the object W will be described below. The inside of the housing 17 is set to be in a vacuum state by a vacuum pump (not shown).

The detection device 10 is communicably connected to the control device 20 by a cable. Thus, each of the excitation source unit 11, the radiation detection unit 12, and the cooling device 16 included in the detection device 10 performs an operation based on a control signal acquired from the control device 20.

The control device 20 includes a first control device 30 and a second control device 40. In this example, the control device 20 is made up of the first control device 30 and the second control device 40 formed separately from the first control device 30, but it may be alternatively made up of the first control device 30 integrally formed with the second control device 40 or the second control device 40 integrally formed with the first control device 30. In this case, the control device 20 has a function of the first control device 30 and a function of the second control device 40.

The first control device 30 is an information processing device such as a desktop personal computer (PC), a notebook PC, or a workstation. The first control device 30 causes the excitation source unit 11 to emit the first radiation R1. The first control device 30 is communicably connected to the second control device 40 by wire or by wireless.

The second control device 40 is an information processing device such as a desktop personal computer (PC), a notebook PC, or a workstation.

The second control device 40 acquires detection information from the radiation detection unit 12. The second control device 40 derives an energy spectrum based on the acquired detection information. That is, the energy spectrum is a energy spectrum based on the electric signal of each of a plurality of rays of second radiation R2 detected by the radiation detection unit 12. The second control device 40 performs a predetermined process based on the derived energy spectrum. The predetermined process is, for example, a process of specifying each of a plurality of elements included in the object W based on the energy spectrum. In place of the process of specifying each of a plurality of elements included in the object W, the predetermined process may be another process based on the energy spectrum.

Here, as described above, when certain second radiation R2 is incident upon the superconductive transition edge sensor T1 (i.e., the radiation detection unit 12), the radiation detection unit 12 outputs an electric signal of a peak value having a correlation with energy of the second radiation R2 to the control device 20 as the detection information indicating that the second radiation R2 is detected. When the baseline varies, the peak value of the electric signal is changed depending on the variation of the baseline. For this reason, in this case, the energy of the second radiation R2 which is calculated based on the peak value of the electric signal and actual energy of the second radiation R2 may not be matched with each other. As a result, an error in the energy spectrum derived by the second control device 40 increases.

In this regard, to suppress mismatch between the energy of the second radiation R2, which is calculated based on the peak value of the electric signal output from the superconductive transition edge sensor T1 when the certain second radiation R2 is incident upon the superconductive transition edge sensor T1 (i.e., the radiation detection unit 12), and the actual energy of the second radiation R2, a radiation analyzing apparatus X (e.g., a conventional radiation analyzing apparatus) different from the radiation analyzing apparatus 1 performs correction of the baseline output by the radiation detection unit 12 or correction of the peak value based on the baseline. However, to perform the correction of the baseline or the correction of the peak value based on the baseline, there is a need to previously acquire various pieces of information used to perform the correction. That is, the radiation analyzing apparatus X should perform an additional process for acquiring the information in order to suppress the mismatch. As a result, the radiation analyzing apparatus X is sometimes difficult to reduce time and effort required for analysis of the object W.

Therefore, the radiation analyzing apparatus 1 detects detection energy that is energy emitted from a reference element that is an element used as a reference among the plurality of elements included in the object W based on the energy spectrum derived using the detection information acquired from the radiation detection unit 12, and corrects the energy spectrum based on reference energy information that is pre-stored information and is information indicating reference energy that is the energy emitted from the reference element and the detected detection energy. Thus, even when the baseline output from the radiation detection unit 12 varies, the radiation analyzing apparatus 1 can provide high-precision energy spectrum while reducing the time required for the analysis of the object W.

Here, the reference element that is the element used as the reference among the plurality of elements included in the object W may be any of desired objects for which a user of the radiation analyzing apparatus 1 does not analyze properties and structures as long as an element, in which K-shell electrons are excited to emit K-rays, is included as the aforementioned reference element. The reason the element, in which the K-shell electrons are excited to emit the K-rays, is the reference element is that energy of the K-rays is hardly changed even when the state of the object W including the reference element is changed. That is, the aforementioned reference energy is the energy of the K-rays in this example, and is a theoretical value calculated by a theory in physics such as quantum mechanics. Instead of the energy of the K-rays, the reference energy may be another energy that is hardly changed even when the state of the object W including the reference element is changed. The state of the object W is a chemical-bonding state of each of the plurality of elements included in the object W. Hereinafter, a description will be given of an example of a case in which the object W includes silicon as the reference element. In place of the silicon, the reference element may be another element, such as aluminum, magnesium, or phosphorus, in which the K-shell electrons are excited to emit the K-rays. Hereinafter, a description will be given of a case in which energy of Kα-rays of K-rays emitted from the silicon is used as the reference energy. This energy is about 1740 eV.

Hereinafter, a process in which the second control device 40 corrects the energy spectrum will be described in detail. Hereinafter, for convenience of description, a process in which the radiation analyzing apparatus 1 irradiates the object W including the plurality of elements with the first radiation R1, detects a plurality of rays of second radiation R2 emitted from the object W irradiated with the first radiation R1 using the radiation detection unit 12, and derives the energy spectrum based on the signal of each of the plurality of rays of the second radiation R2 detected by the radiation detection unit 12 will be described in the name of the analysis of the object W.

### <Functional Configurations of First and Second Control Devices>

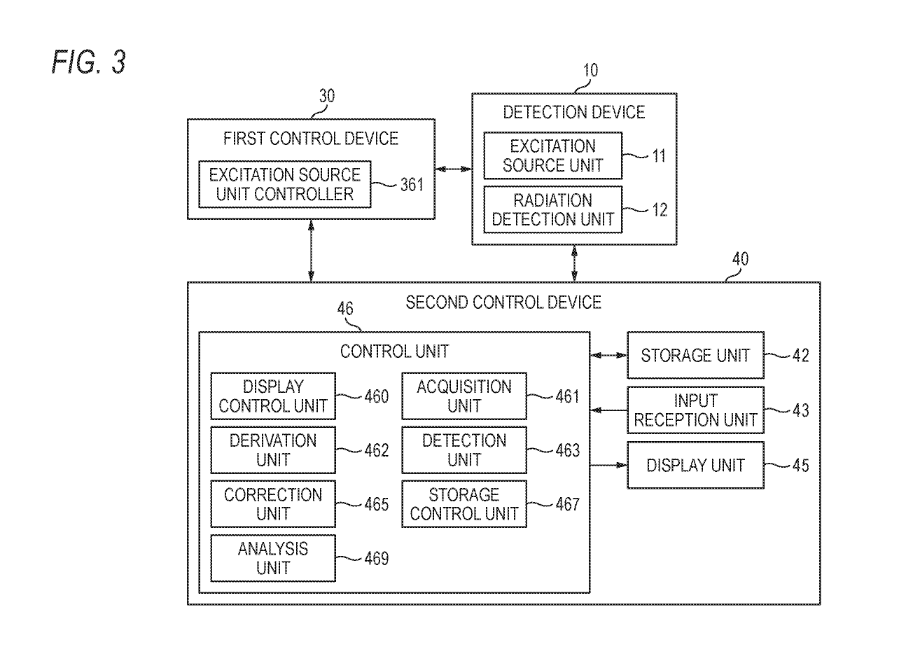

Hereinafter, functional configurations of the first and second control devices 30 and 40 will be described with reference to FIG. 3. FIG. 3 is a view illustrating an example of the first and second control devices 30 and 40.

The first control device 30 includes an excitation source unit controller 361. For example, a central processing unit (CPU) (not shown) executes various programs stored in a storage unit, and thus the excitation source unit controller 361 is realized.

The excitation source unit controller 361 controls the excitation source unit 11 to emit the first radiation R1 based on an operation performed by the user of the radiation analyzing apparatus 1. In addition, the excitation source unit controller 361 controls the excitation source unit 11 to emit the first radiation R1 at the request of the second control device 40.

The second control device 40 includes a storage unit 42, an input reception unit 43, a display unit 45, and a control unit 46.

The control unit 46 controls the entire second control device 40. The control unit 46 includes a display control unit 460, an acquisition unit 461, a derivation unit 462, a detection unit 463, a correction unit 465, a storage control unit 467, and an analysis unit 469. For example, a CPU (not shown) executes various programs stored in the storage unit 42 that is a hard disk drive (HDD), a solid state drive (SSD) or the like, and thus these functional units included in the control unit 46 are realized.

The display control unit 460 generates various screens based on a user operation received via the input reception unit 33 that is an input device such as a keyboard, a mouse, or the like. The display control unit 460 displays the generated screen on the display unit 45 that is a liquid crystal display or the like.

The acquisition unit 461 acquires detection information from the radiation detection unit 12.

The derivation unit 462 derives an energy spectrum based on the detection information acquired by the acquisition unit 461.

The detection unit 463 detects detection energy, which is energy emitted from a reference element that is an element used as a reference among a plurality of elements included in the object W, based on the energy spectrum derived by the derivation unit 462.

The correction unit 465 corrects the energy spectrum derived by the derivation unit 462 based on reference energy information, which is previously stored in the storage unit 42 and indicates reference energy that is energy emitted from the reference element, and the detection energy detected by the detection unit 463.

The storage control unit 467 stores the detection information acquired by the acquisition unit 461 in the storage unit 42.

The analysis unit 469 analyzes properties and a structure of the object W based on the energy spectrum corrected by the correction unit 465. For example, the analysis unit 469 performs the above predetermined process described above based on the energy spectrum corrected by the correction unit 465.

<Process in which Second Control Device Corrects Energy Spectrum>

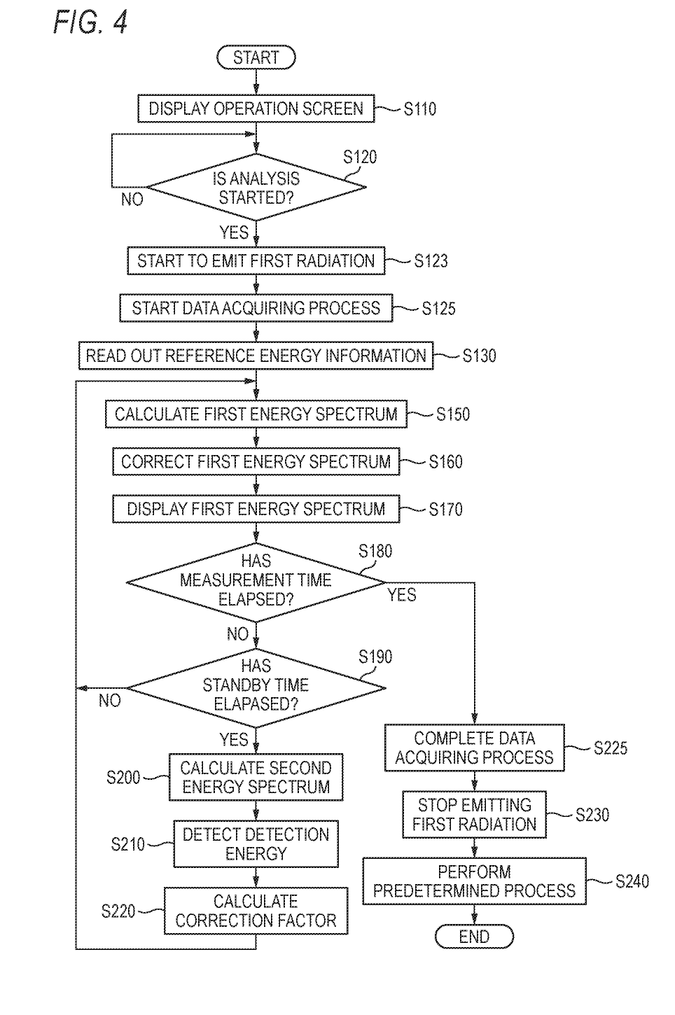

Hereinafter, a specific example of a process in which the second control device 40 corrects the energy spectrum will be described with reference to FIG. 4. FIG. 4 is a flow chart illustrating an example of a flow of the process in which the second control device 40 corrects the energy spectrum. Hereinafter, a description will be given of a case in which the object W irradiated with the first radiation R1 from the excitation source unit 11 inside the housing 17 is previously disposed at a predetermined disposition position. In addition, hereinafter, a description will be given of a case in which at which the radiation detection unit 12 is previously disposed at a position at which the second radiation R2 emitted from the object W disposed at a predetermined disposition position can be detected.

In step S110, the display control unit 460 generates an operation screen, which receives a user operation (analysis start operation) of starting an analysis of the object W with using the radiation analyzing apparatus 1, based on an operation by the user of the radiation analyzing apparatus 1. The display control unit 460 displays the generated operation screen on the display unit 45. The control unit 46 transitions to step S120.

In step S120, the control unit 46 is on standby until the analysis start operation by the user is received via the operation screen displayed on the display unit 45 in step S110. When the analysis start operation by the user is received via the operation screen (YES in step S120), the excitation source unit controller 361 transitions to step S123.

In step S123, the excitation source unit controller 361 controls the excitation source unit 11, and starts irradiating the object W with the first radiation R1. Each of the acquisition unit 461 and the storage control unit 467 transitions to step S125. The object W irradiated with the first radiation R1 emits the second radiation R2.

In step S125, each of the acquisition unit 461 and the storage control unit 467 starts a data acquiring process. To be specific, in the data acquiring process, the acquisition unit 461 acquires detection information from the radiation detection unit 12 whenever the radiation detection unit 12 detects the second radiation R2. Here, the detection information is detection information that is output to the acquisition unit 461 whenever the radiation detection unit 12 detects the second radiation R2 emitted from the object W, and detection information that corresponds to the second radiation R2 detected by the radiation detection unit 12. In the data acquiring process, the storage control unit 467 converts the detection information, which is acquired by the acquisition unit 461 whenever the acquisition unit 461 acquires the detection information from the radiation detection unit 12, into detection information that indicates energy corresponding to a peak value of the detection information (i.e., a peak value of an electric signal as the detection information). The storage control unit 467 stores the converted detection information in the storage unit 42 while being made to correspond to time information indicating a current time. This data acquiring process performed by each of the acquisition unit 461 and the storage control unit 467 is continued until an end condition designated by the user via the operation screen displayed on the display unit 45 and received by the control unit 46 in step S110 is satisfied. The end condition is for instance that a measurement time designated by the user via the operation screen and received by the control unit 46 has lapsed since the analysis start operation by the user is received via the operation screen. The end condition may be another condition. After each of the acquisition unit 461 and the storage control unit 467 starts the data acquiring process, the correction unit 465 transitions to step S130. Hereinafter, for convenience of description, a period that the measurement time elapses since the analysis start operation by the user is received will be described in the name of a measurement period.

In step S130, the correction unit 465 reads the reference energy information pre-stored in the storage unit 42 out of the storage unit 42 based on an operation by the user via the aforementioned operation screen. For example, before the user performs the analysis start operation via the operation screen, the user can input the reference energy into an entry field which is provided on the operation screen and into which the reference energy is input. When the reference energy is input into the entry field by the user, the storage control unit 467 stores the reference energy information, which indicates the reference energy input into the entry field, in the storage unit 42. The correction unit 465 reads the reference energy information, which is stored in the storage unit 42 in this way, out of the storage unit 42 in step S130. The derivation unit 462 transitions to step S150.

In step S150, the derivation unit 462 derives (calculates) a first energy spectrum that is an energy spectrum based on one or more pieces of detection information which are stored in the storage unit 42 up to now. A method in which the derivation unit 462 derives (calculates) the first energy spectrum based on the one or more pieces of detection information in step S150 may be a known method or a method developed from this method.

In step S60, the correction unit 465 reads correction factor information, which is previously stored in the storage unit 42 and indicates a correction factor, out of the storage unit 42. Here, the correction factor information read out of the storage unit 42 in a first process of step S160 is information indicating 1 (one) as the correction factor. The correction factor information is pre-stored in the storage unit 42 at a moment before the first process of step S160 is performed. Meanwhile, since the correction factor information read out of the storage unit 42 in second or later processes of step S160 is updated whenever a process of step S220 (to be described below) is performed, the correction factor information is not necessarily limited to the information indicating 1 (one) as the correction factor. The correction unit 465 corrects the first energy spectrum, which is derived by the derivation unit 462 in step S150, based on the correction factor information read out of the storage unit 42. To be specific, the correction unit 465 corrects the first energy spectrum by multiplying the first energy spectrum by the correction factor which the correction factor information read out of the storage unit 42 indicates. Here, multiplying the first energy spectrum by the correction factor refers to multiplying energy of the first energy spectrum by the correction factor. After the correction unit 465 corrects the first energy spectrum, the display control unit 460 transitions to step S170. Details of the first energy spectrum corrected by the correction unit 465 will be described below.

In step S170, the display control unit 460 displays the information, which indicates the first energy spectrum corrected by the correction unit 465 in step S160, on the display unit 45. For example, the display control unit 460 displays the information on the aforementioned operation screen. The information may be a graph in which a curve of a fitting function fitted to the first energy spectrum is plotted, a histogram that indicates the first energy spectrum, and other information that indicates the first energy spectrum. After the display control unit 460 displays the information indicating the first energy spectrum on the display unit 45, the derivation unit 462 transitions to step S180.

In step S180, the derivation unit 462 determines whether or not the measurement time designated by the user via the operation screen has elapsed since the analysis start operation by the user is received via the operation screen in step S120. The measurement time is a time that is estimated to be sufficient to complete the analysis of the object W, and for instance two hours. The measurement time may be a time shorter than two hours, or a time longer than two hours. When it is determined that the measurement time has not elapsed from the time (NO in step S180), the derivation unit 462 transitions to step S190. On the other hand, when the derivation unit 462 determines that the measurement time has elapsed from the time (YES in step S180), each of the acquisition unit 461 and the storage control unit 467 transitions to step S225.

In step S190, the derivation unit 462 determines whether or not a standby time has elapsed. To be specific, in a first process of step S190, the derivation unit 462 determines whether or not the standby time has elapsed from the time when the analysis start operation is received. In second or later processes of step S190, the derivation unit 462 determines whether or not the standby time has again elapsed from the time when it is determined that the standby time has elapsed in the previous process of step S190. The standby time is a time that defines a moment (or an interval) at which the correction unit 465 updates the correction factor information stored in the storage unit 42. The standby time is for instance 10 seconds. The standby time may be a time shorter than 10 seconds or a time longer than 10 seconds. When it is determined that the standby time has not elapsed (No in step S190), the derivation unit 462 transitions to step S150. On the other hand, when it is determined that the standby time has elapsed (YES in step S190), the derivation unit 462 transitions to step S200.

In step S200, the derivation unit 462 derives (extracts) a second energy spectrum, which is a part of the first energy spectrum derived in step S150 performed just before, from the first energy spectrum. The second energy spectrum is a partial energy spectrum included in the first energy spectrum in this example, and is a partial energy spectrum in a predetermined energy range including the reference energy which the reference energy information read out of the storage unit 42 by the correction unit 465 in step S130 indicates. The predetermined energy range is for instance a range between energy lower than the reference energy by a predetermined value and energy higher than the reference energy by a predetermined value. The predetermined value is for instance 10% of the reference energy. The predetermined value may be a value lower than 10% of the reference energy or a value higher than 10% of the reference energy. The predetermined energy range may be the same as an energy range of the first energy spectrum. Instead of the configuration in which the derivation unit 462 derives (extracts) a second energy spectrum, which is a part of the first energy spectrum derived in step S150 performed just before, from the first energy spectrum, a configuration in which the energy spectrum of the predetermined energy range is calculated as the second energy spectrum based on the detection information stored in the storage unit 42 up to now may be adopted. After the derivation unit 462 derives the second energy spectrum, the detection unit 463 transitions to step S210.

In step S210, the detection unit 463 detects energy emitted from silicon (a reference element in the example) included in the object W as detection energy based on the second energy spectrum derived (extracted) by the derivation unit 462 in step S200. To be specific, in step S210, the detection unit 463 detects energy of K-rays emitted from silicon as detection energy. In this example, since the reference energy is energy of Kα-rays of silicon, the K-rays are the Kα-rays (the Si-Kα-rays). The K-rays may be other K-rays such as Kβ-rays. After the detection unit 463 detects the detection energy, the correction unit 465 transitions to step S220.

In step S220, the correction unit 465 calculates the aforementioned correction factor based on the detection energy detected by the detection unit 463 in step S210 and the reference energy information read out of the storage unit 42 in step S130. Hereinafter, as an example, a case in which 1735 eV is detected as the detection energy by the detection unit 463 in step S210 will be described. The correction unit 465 calculates a value given by dividing the reference energy which the reference energy information indicates by the detection energy (a ratio of the reference energy to the detection energy) as the aforementioned correction factor. As described above, in this example, since the reference energy is 1740 eV and the detection energy is 1735 eV, the correction factor is (1740/1735). The correction unit 465 erases the correction factor information pre-stored in the storage unit 42 from the storage unit 42, and newly stores the correction factor information indicating the calculated correction factor in the storage unit 42. That is, the correction unit 465 updates the correction factor information pre-stored in the storage unit 42 to the correction factor information indicating the calculated correction factor. The derivation unit 462 transitions to step S150. In this way, the correction unit 465 receives the analysis start operation, and then updates the correction factor information whenever the standby time has elapsed.

In step S225, each of the acquisition unit 461 and the storage control unit 467 completes the data acquiring process. To be specific, the acquisition unit 461 stops (completes) the acquisition of the detection information from the radiation detection unit 12. Along with the stop of the acquisition, the storage control unit 467 stops storing the detection information in the storage unit 42. The control unit 46 transitions to step S230.

In step S230, the control unit 46 outputs a request to stop the excitation source unit 11 from emitting the first radiation R1 to the excitation source unit controller 361 of the first control device 30. The excitation source unit controller 361 acquiring the request controls the excitation source unit 11 to stop emitting the first radiation R1. The analysis unit 469 transitions to step S240.

In step S240, the analysis unit 469 performs the predetermined process described above based on the first energy spectrum corrected by the correction unit 465 in step S160 performed finally. The control unit 46 completes the process.

In this way, the second control device 40 corrects the derived first energy spectrum based on the reference energy and the detection energy that have been described above. Thus, the radiation analyzing apparatus 1 can provide the high-precision energy spectrum while reducing the time required for the analysis of the object W. Especially, even when the time required for the analysis of the object W is long, the radiation analyzing apparatus 1 can calculate the high-precision energy spectrum, and perform the process based on the calculated energy spectrum with high precision.

The radiation analyzing apparatus 1 may be configured to perform the derivation of the first energy spectrum described above on one or more regions of interest (ROIs) previously designated by the user (i.e., to perform mapping). In this case, the radiation analyzing apparatus 1 corrects the first energy spectrum derived for each of the one or more ROIs based on the reference energy and the detection energy that have been described above.

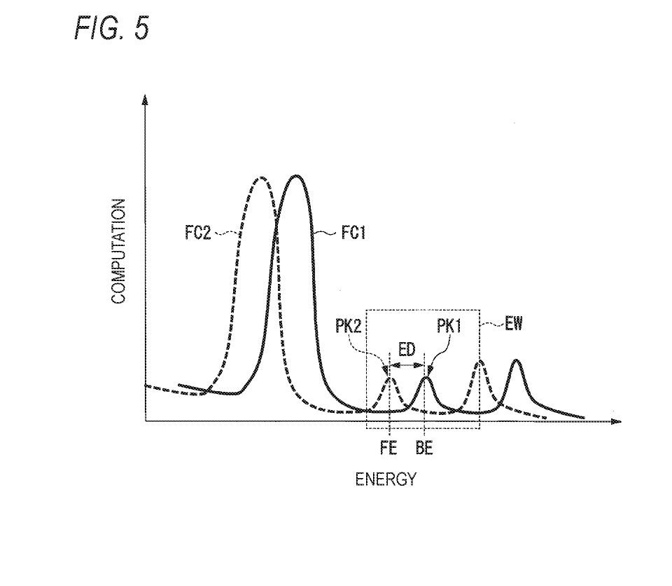

Here, the first energy spectrum will be described with reference to FIG. 5. FIG. 5 is a graph illustrating an example of the first energy spectrum derived by the derivation unit 462 in step S150. The horizontal axis in the graph represents energy. The vertical axis in the graph represents a count that is the number of times which the second radiation R2 corresponding to each energy is detected by the radiation detection unit 12. A curve FC1 in the graph indicates the first energy spectrum derived by the derivation unit 462. To be more specific, the curve FC1 indicates the fitting function fitted to the first energy spectrum. A peak PK1 represented in the graph is one of a plurality of peaks in the curve FC1, and the peak of Kα-rays emitted from silicon that is the reference element in this example. Energy BE represented in the graph is energy detected based on the peak PK1. Hereinafter, for convenience of description, a case in which the energy BE is matched with the aforementioned reference energy (1740 eV in this example) will be described by way of example.

As described above, when the baseline output by the radiation detection unit 12 varies, the first energy spectrum is charged depending on the variation of the baseline. For example, when the baseline varies, the curve FC indicating the first energy spectrum illustrated in FIG. 5 is shifted to a low energy side of the horizontal axis of the graph illustrated in FIG. 5 up to a position at which the curve FC1 is matched with a curve FC2 illustrated in FIG. 5 depending on the variation. A peak PK2 illustrated in FIG. 5 is one of a plurality of peaks in the curve FC2, and the peak of Kα-rays emitted from silicon that is the reference element in this example. Energy FE represented in the graph is energy detected based on the peak PK2. In this case, the energy of the Kα-rays emitted from silicon is detected as the energy FE by the detection unit 463 based on the peak PK2. An energy difference ED illustrated in FIG. 5 is a difference between the energy BE and the energy FE.

The correction unit 465 multiplies the first energy spectrum indicated by the curve FC2 by the correction factor calculated in step S220, thereby shifting the first energy spectrum to a high energy side along the horizontal axis in the graph illustrated in FIG. 5, and correcting the first energy spectrum such that the first energy spectrum nearly overlaps the first energy spectrum indicated by the curve FC1. Thus, the radiation analyzing apparatus 1 can provide the high-precision energy spectrum while reducing the time required for the analysis of the object W.

Here, a partial spectrum EW that is a part of the first energy spectrum indicated by the curve FC2 illustrated in FIG. 5 is an example of the second energy spectrum derived (extracted) by the derivation unit 462 in step S200. The derivation unit 462 derives (extracts) a partial energy spectrum, which is a part of the first energy spectrum and is in a range between energy lower than the energy BE by a predetermined value and energy higher than the energy BE by a predetermined value, from the first energy spectrum indicated by the curve FC2 as the second energy spectrum. That is, as illustrated in FIG. 5, the predetermined value described above is a value selected such that the energy FE is included in the range. The detection unit 463 detects the energy (the energy FE in the example illustrated in FIG. 5), which is emitted from silicon included in the object W (the reference element in this example), as the detection energy based on the second energy spectrum.

Since FIG. 5 is depicted to make the energy difference ED clear, the energy range of the partial spectrum EW is not matched with the range between the energy lower than the energy BE by the predetermined value and the energy higher than the energy BE by the predetermined value. The graph illustrated in FIG. 5 is depicted for description, and each of the peak PK1 of the curve FC1 and the peak PK2 of the curve FC2 is not necessarily matched with the peak of the Kα-rays emitted from actual silicon.

The reference energy described above may be energy absorbed in the reference element instead of the energy emitted from the reference element. In this case, the reference energy is energy absorbed in electrons of the reference element when the electrons are excited. To be specific, in this case, in this example, the reference energy is energy absorbed in K-shell electrons of the reference element when the electrons are excited. In this case, the reference energy may be other energy absorbed in the electrons of the reference element when the electrons are excited, such as energy absorbed in L-shell electrons of the reference element when the electrons are excited. In this case, the detection unit 463 detects the energy absorbed in K-shell electrons of the reference element as the detection energy based on an absorption edge of the energy spectrum derived by the derivation unit 462. In this case, the reference element may be an element included in an X-ray transmission window, an X-ray lens, etc. included in the detection device 10 instead of the element included in the object W. In this case, the object W may not include the reference element.

The reference element may be an element included in an object for calibration which is different from the object W instead of the element included in the object W. In this case, the control unit 46 controls the first control device 30, for instance, before the process of step S200 is performed, and causes the excitation source unit 11 to irradiate the object for calibration with the first radiation R1 whenever the aforementioned standby time has elapsed. The radiation detection unit 12 detects the second radiation R2 emitted from the object for calibration, and outputs an electric signal having a peak value corresponding to energy of the detected second radiation R2 to the second control device 40, as second detection information. The acquisition unit 461 acquires the second detection information from the radiation detection unit 12. The storage control unit 467 converts the second detection information acquired by the acquisition unit 461 into second detection information indicating that the second radiation R2 of the energy corresponding to a peak value of the second detection information acquired by the acquisition unit 461 (i.e., a peak value of an electric signal as the second detection information) is detected. The storage control unit 467 stores the converted second detection information in the storage unit 42 while being made to correspond to time information indicating a current time. In step S200, the derivation unit 462 derives the second energy spectrum based on the second detection information stored in the storage unit 42. In this case, the object W may not include the reference element. Meanwhile, the object for calibration preferably has a simple configuration. For example, the object for calibration is formed of silicon, aluminum, or the like, but it is not limited thereto.

The acquisition unit 461 and the derivation unit 462 described above act as pulse height analyzers, and may be formed separately from the second control device 40. In this case, the radiation analyzing apparatus 1 includes the detection device 10, the pulse height analyzers, and the second control device 40. The pulse height analyzers acquire the electric signal corresponding to the second radiation R2 detected by the radiation detection unit 12, and derive energy spectrum based on the acquired electric signal. The second control device 40 acquires the energy spectrum from the pulse height analyzers.

In step S220, the correction unit 465 described above may be configured to calculate a value of the reference energy to an average value of two or more detection energies detected previously by the detection unit 463 as the correction factor. In this case, for example, when the average value is B, and the reference energy is A, the ratio in the correction unit 465 is A/B. The two or more detection energies may be all detection energies stored in the storage unit 32 within a time from the present time to a time going back to a predetermined period, be detection energies that are randomly selected from among all of the detection energies, be detection energies that are selected from among all of the detection energies based on a predetermined rule, or be detection energies that are selected by another method.

The derivation unit 462 is configured to derive each of the first energy spectrum and the second energy spectrum at a moment during the aforementioned measurement period in the flow chart illustrated in FIG. 4. However, in place of this configuration, the derivation unit 462 may be configured to derive the first energy spectrum at a moment during the measurement period and to calculate the second energy spectrum at a moment out of the measurement period. For example, after the derivation unit 462 derives the first energy spectrum at a moment during the measurement period, and stores the derived first energy spectrum in the storage unit 42, the control unit 46 may be configured to perform the process of step S230 at a moment out of the measurement period, and to derive the second energy spectrum based on the detection information stored in the storage unit 42. In this case, the correction unit 465 corrects the first energy spectrum after the second energy spectrum is derived.

The detection unit 463 described above is configured to detect the detection energy based on the second energy spectrum calculated by the derivation unit 462 after the derivation unit 462 calculates the first energy spectrum in the flow chart illustrated in FIG. 4. However, in place of this configuration, the detection unit 463 configured to detect the detection energy based on the second energy spectrum calculated by the derivation unit 462 at a moment before the derivation unit 462 derives the first energy spectrum, or at both of moments before and after the derivation unit 462 derives the first energy spectrum.

The detection unit 463 described above is configured to detect the detection energy based on the second energy spectrum derived by the derivation unit 462 at a moment during a period that the derivation unit 462 derives the first energy spectrum. In this case, the derivation unit 462 completes the calculation of the second energy spectrum before completing the derivation of the first energy spectrum. Thus, the radiation analyzing apparatus 1 can further reduce the time required for the analysis of the object W.

As described above, the radiation analyzing apparatus 1 in the embodiment irradiates the object (the object W in this example) including the plurality of elements with the first radiation (the first radiation R1 in this example), detects the plurality of rays of the second radiation (the second radiation R2 in this example) emitted from the object irradiated with the first radiation using the radiation detection unit (the radiation detection unit 12 in this example), calculates the energy spectrum based on the signal of each of the plurality of rays of the second radiation detected by the radiation detection unit, detects the detection energy, which is either the energy absorbed in the reference element (silicon in this example) that is the element used as the reference or is the energy emitted from the reference element, based on the calculated energy spectrum, and corrects the calculated energy spectrum based on the reference energy information, which is previously stored in the storage unit (the storage unit 42 in this example) and indicates the reference energy that is the energy absorbed in the reference element or the energy emitted from the reference element, and the detected detection energy. Thus, the radiation analyzing apparatus 1 can provide the high-precision energy spectrum while reducing the time required for the analysis of the object.

The radiation analyzing apparatus 1 calculates, as the energy spectrum, each of the first energy spectrum within the first energy range designated by the user, and the second energy spectrum within the second energy range including the reference energy, and detects the detection energy based on the second energy spectrum. Thus, the radiation analyzing apparatus 1 can provide the high-precision energy spectrum based on the second energy spectrum while reducing the time required for the analysis of the object.

In the radiation analyzing apparatus 1, the first energy range and the second energy range are the same. The radiation analyzing apparatus 1 calculates one energy spectrum based on the signal of each of the plurality of rays of the second radiation detected by the radiation detection unit as the first energy spectrum and the second energy spectrum. Thus, the radiation analyzing apparatus 1 can provide the high-precision energy spectrum based on the first energy spectrum and the second energy spectrum calculated as one energy spectrum while reducing the time required for the analysis of the object.

The radiation analyzing apparatus 1 calculates the first energy spectrum at a moment during the measurement period that the measurement time designated by the user has elapsed since the user operation of starting the analysis of the object is received, and calculates the second energy spectrum at a moment out of the measurement period.

Thus, the radiation analyzing apparatus 1 can calculate the second energy spectrum at an arbitrary moment after the first energy spectrum is calculated.

The radiation analyzing apparatus 1 may calculate the first energy spectrum and the second energy spectrum at a moment during the measurement period that the measurement time designated by the user has elapsed since the user operation of starting the analysis of the object is received. Thus, the radiation analyzing apparatus 1 can calculate the first energy spectrum and the second energy spectrum at an arbitrary moment between the times. As a result, the radiation analyzing apparatus 1 can provide the high-precision energy spectrum while reducing the time required for the analysis of the object.

The radiation analyzing apparatus 1 detects the detection energy whenever it calculates the second energy spectrum, and corrects the calculated first energy spectrum whenever it detects the detection energy. Thus, the radiation analyzing apparatus 1 can correct the first energy spectrum whenever it calculates the second energy spectrum.

The radiation analyzing apparatus 1 detects the detection energy based on the calculated second energy spectrum at one or both of a moment before calculating the first energy spectrum and a moment after calculating the first energy spectrum. Thus, the radiation analyzing apparatus 1 can correct the first energy spectrum at an arbitrary moment.

The radiation analyzing apparatus 1 detects the detection energy based on the calculated second energy spectrum at a moment during a period of calculating the first energy spectrum. Thus, the radiation analyzing apparatus 1 can further reduce the time required for the analysis of the object.

The radiation analyzing apparatus 1 corrects the calculated energy spectrum based on the ratio between the reference energy indicated by the reference energy information stored in the storage unit and the detection energy detected by the detection unit (the detection unit 463 in this example). Thus, the radiation analyzing apparatus 1 can provide the high-precision energy spectrum based on the ratio between the reference 30 energy and the detection energy while reducing the time required for the analysis of the object.

The radiation analyzing apparatus 1 multiplies the calculated energy spectrum by the ratio between the reference energy and the detection energy, thereby correcting the calculated energy spectrum. Thus, the radiation analyzing apparatus 1 multiplies the calculated energy spectrum by the ratio between the reference energy and the detection energy, so that it can provide the high-precision energy spectrum while reducing the time required for the analysis of the object.

The radiation analyzing apparatus 1 corrects the calculated energy spectrum based on the one or more detection energies detected previously by the detection unit and the reference energy. Thus, the radiation analyzing apparatus 1 can provide the high-precision energy spectrum based on the one or more detection energies detected previously by the detection unit and the reference energy while reducing the time required for the analysis of the object.

In the radiation analyzing apparatus 1, the energy absorbed in the reference element is the energy absorbed in the K-shell electrons of the reference element when the electrons are excited, and the energy emitted from the reference element is the energy of the K-rays emitted from the reference element. Thus, the radiation analyzing apparatus 1 can provide the high-precision energy spectrum based on the energy absorbed in the K-shell electrons of the reference element when the electrons are excited or the energy of the K-rays emitted from the reference element while reducing the time required for the analysis of the object.

In the radiation analyzing apparatus 1, the reference element is any of elements, in each of which the K-shell electrons thereof are excited, and thus emit the K-rays. Therefore, the radiation analyzing apparatus 1 can provide the high-precision energy spectrum based on the element in which the K-shell electrons thereof are excited and thereby emit the K-rays while reducing the time required for the analysis of the object.

In the radiation analyzing apparatus 1, the excitation source unit irradiates an electron beam as the first radiation, and the radiation detection unit has the superconductive transition edge sensor (the superconductive transition edge sensor T1 in this example) that detects the X-rays, as the second radiation, generated from the object irradiated with the electron beam. Thus, the radiation analyzing apparatus 1 that is an X-ray analyzing apparatus having the superconductive transition edge sensor can provide the high-precision energy spectrum while suppressing a change in detection sensitivity of the radiation detection unit and reducing the time required for the analysis of the object.

As described above, the embodiment of the invention has been described in detail with reference to the drawings. However, a specific configuration thereof is not limited to this embodiment, and may be modified, substituted, and deleted without departing from the scope of the invention.

A program for realizing the function of an arbitrary component in the aforementioned device (e.g., the control device 20) may be recorded in a computer-readable recording medium, and may be executed by being read by a computer system.

Meanwhile, it is assumed that the wording “computer system” used herein includes hardware such as an operating system (OS) or a peripheral device. In addition, the “computer-readable recording medium” refers to a portable medium such as a flexible disc, a magneto-optical disc, a ROM, or a compact disk (CD)-ROM, or a storage device such as a hard disk that is mounted in a computer system. Further, it is assumed that the “computer-readable recording medium” holds a program for a fixed period of time, like a volatile memory (RAM) inside a computer system serving as a server or a client in a case where the program is transmitted through a network such as the Internet or a communication line such as a telephone line.

In addition, the program may be transmitted to another computer system through a transmission medium or by transmission waves in the transmission medium, from a computer system in which the program is stored in a storage device or the like. Here, the “transmission medium” transmitting the program refers to a medium having a function of transmitting information, like a network (a communication network) such as the Internet or a communication line such as a telephone line.

In addition, the program may be a program for realizing a portion of the aforementioned functions. Further, the program may be a so-called difference file (a differential program) capable of realizing the aforementioned functions in combination with a program which is already recorded in a computer system.

What is claimed is:

1. A radiation analyzing apparatus comprising:
an excitation source unit configured to irradiate an object including a plurality of elements with a first radiation;
a radiation detection unit configured to detect a plurality of rays of a second radiation emitted from the object irradiated with the first radiation;
a derivation unit configured to derive an energy spectrum based on a signal of each of the plurality of rays of the second radiation detected by the radiation detection unit;
a detection unit configured to detect detection energy, which is energy absorbed in a reference element that is an element used as a reference or is energy emitted from the reference element, based on the energy spectrum derived by the derivation unit; and
a correction unit configured to correct the energy spectrum derived by the derivation unit based on reference energy information, which is previously stored in a storage unit and indicates reference energy that is energy absorbed in the reference element or is energy emitted from the reference element, and the detection energy detected by the detection unit.

2. The radiation analyzing apparatus according to claim 1,
wherein the derivation unit derives, as the energy spectrum, each of a first energy spectrum within a first energy range designated by a user of the radiation analyzing apparatus, and a second energy spectrum within a second energy range including the reference energy, and
the detection unit detects the detection energy based on the second energy spectrum.

3. The radiation analyzing apparatus according to claim 2,
wherein the second energy range is included in the first energy range and is identical to the first energy range, and
the derivation unit uses a part of the first energy spectrum as the second energy spectrum.

4. The radiation analyzing apparatus according to claim 2,
wherein the derivation unit derives the first energy spectrum at a moment during a measurement period that a measurement time designated by the user elapses since a user operation of starting an analysis of the object is received, and derives the second energy spectrum at a moment out of the measurement period.

5. The radiation analyzing apparatus according to claim 2,
wherein the derivation unit derives the first energy spectrum and the second energy spectrum at a moment during a period that a measurement time designated by the user elapses since a user operation of starting an analysis of the object is received.

6. The radiation analyzing apparatus according to claim 2,
wherein the detection unit detects the detection energy whenever the derivation unit derives the second energy spectrum, and
the correction unit corrects the first energy spectrum derived by the derivation unit whenever the detection unit detects the detection energy.

7. The radiation analyzing apparatus according to claim 2,
wherein the detection unit detects the detection energy based on the second energy spectrum derived by the derivation unit at one or both of a moment before the derivation unit derives the first energy spectrum and a moment after the derivation unit derives the first energy spectrum.

8. The radiation analyzing apparatus according to claim 5,
wherein the detection unit detects the detection energy based on the second energy spectrum derived by the derivation unit at a moment during a period that the derivation unit derives the first energy spectrum.

9. The radiation analyzing apparatus according to claim 1,
wherein the correction unit corrects the energy spectrum derived by the derivation unit based on a ratio between the detection energy detected by the detection unit and the reference energy indicated by the reference energy information stored in the storage unit.

10. The radiation analyzing apparatus according to claim 9,
wherein the correction unit multiplies the energy spectrum derived by the derivation unit by the ratio to correct the energy spectrum derived by the derivation unit.

11. The radiation analyzing apparatus according to claim 1,
wherein the correction unit corrects the energy spectrum derived by the derivation unit based on one or more of the detection energies detected previously by the detection unit and the reference energy.

12. The radiation analyzing apparatus according to claim 1,
wherein the energy absorbed in the reference element is energy absorbed in electrons of the reference element when the electrons are excited, and
the energy emitted from the reference element is energy of K-rays emitted from the reference element.

13. The radiation analyzing apparatus according to claim 1,
wherein the reference element is any of elements in which K-shell electrons are excited to emit K-rays.

14. The radiation analyzing apparatus according to claim 1,
wherein the excitation source unit emits an electron beam as the first radiation, and
the radiation detection unit has a superconductive transition edge sensor that detects X-rays, as the second radiation, generated from the object irradiated with the electron beam.
